(19) United States
(12) Patent Application Publication
(10) Pub. No.: US 2015/0187661 A1
(43) Pub. Date: Jul. 2, 2015

(54) DUAL LAYER HARDMASK FOR EMBEDDED EPI GROWTH

(71) Applicant: Texas Instruments Incorporated, Dallas, TX (US)

(72) Inventors: Tom Lii, Plano, TX (US); David Farber, Plano, TX (US)

(21) Appl. No.: 14/575,512

(22) Filed: Dec. 18, 2014

Related U.S. Application Data
(60) Provisional application No. 61/921,567, filed on Dec. 30, 2013.

(51) Int. Cl. H01L 21/8238; H01L 21/3065; H01L 21/308; H01L 21/311

(52) U.S. Cl. CPC H01L 21/823864; H01L 21/823814; H01L 21/31144; H01L 21/3065; H01L 21/3081

(57) ABSTRACT

A process for forming an integrated circuit with an embedded epitaxially grown semiconductor using an epi blocking bilayer. The epi blocking bilayer comprised of a two different materials that may be etched selectively with respect to each other such as silicon nitride and silicon dioxide.

### CROSS-REFERENCE TO RELATED APPLICATIONS

This application claims the benefit of priority under U.S.C. §119(e) of U.S. Provisional Application 61/921,567 (Texas Instruments docket number TI-71242, filed Dec. 30, 2013), the contents of which are hereby incorporated by reference.

### FIELD OF INVENTION

This invention relates to the field of integrated circuits. More particularly, this invention relates to embedded epitaxial layers in integrated circuits.

### BACKGROUND

Transistor performance has failed to keep pace with the rapid reduction in geometries because of short channel limitations. One method to improve transistor performance is to apply stress to the channel region of transistors to increase carrier mobility. Tensile stress may be applied to NMOS transistors to enhance electron mobility and compressive stress may be applied to PMOS transistors to enhance hole mobility.

The most commonly used method to apply stress to the PMOS channel is to replace silicon in the PMOS source and drains with SiGe. Trenches are etched into the single crystal silicon in the source and drains of PMOS transistors and refilled with epitaxially grown single crystal SiGe. SiGe has a larger lattice constant than single crystal silicon and therefore applies compressive stress to the PMOS transistor channel.

Silicon may be etched from the source and drains of NMOS transistors and refilled with epitaxially grown SiC which has a smaller lattice constant and therefore applies tensile stress to the NMOS transistor channel.

Defects in SiGe may be generated when the SiGe is epitaxially grown in a trench around horizontal (a corner in the side of the trench) or vertical (a corner at the top of the trench) convex corners. Common practice is to add design rules that forbid horizontal convex corners where SiGe is to be epitaxially grown.

Vertical convex corners cannot be forbidden with design rules. Vertical convex corners may only be avoided with process control.

Another problem that may occur is epitaxial growth of SiGe on polysilicon if any portion of the polysilicon gate is exposed. Epi protrusions that grow on exposed polysilicon may result in contact to gate shorts.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A process for forming an integrated circuit with an embedded epitaxially grown semiconductor using an epi blocking bilayer. The epi blocking bilayer comprised of a two different materials that may be etched selectively with respect to each other such as silicon nitride and silicon dioxide.

### BRIEF DESCRIPTION OF THE DRAWINGS

FIG. 1A-1D (Prior art) are illustrations of steps in the fabrication of integrated circuits formed according commonly used methods.

FIG. 2A-2E are illustrations of steps in the fabrication of integrated circuits formed according to principles of the invention.

FIGS. 3A-3C are illustrations of steps in the fabrication of integrated circuits formed according to principles of the invention.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

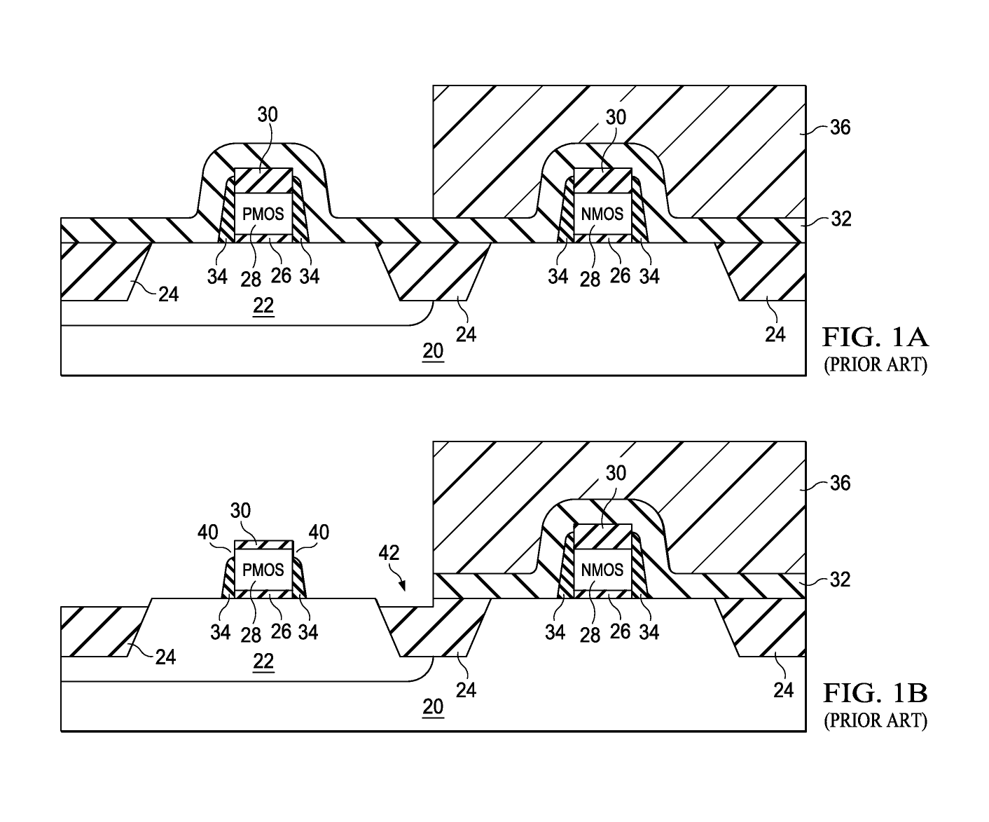

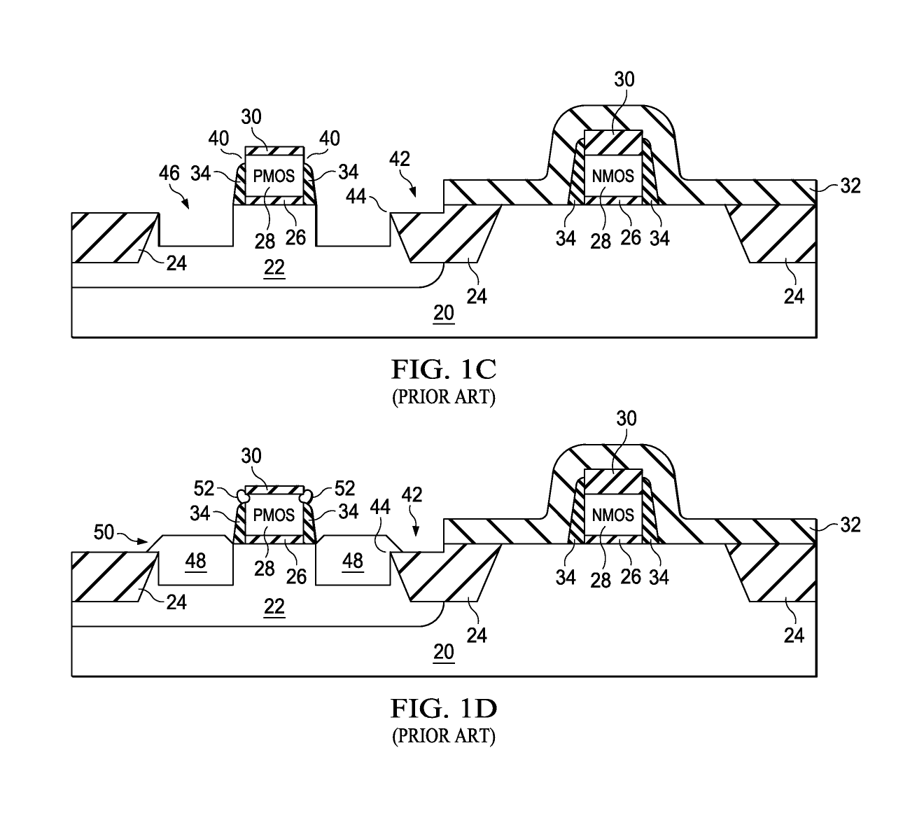

A conventional process flow for forming SiGe source and drains on a PMOS transistor is illustrated in FIGS. 1A-1D.

FIG. 1A shows an NMOS transistor over p-type substrate 20 and a PMOS transistor over nwell 22. Shallow trench isolation dielectric (STI) 24 electrically isolates the transistors. The transistor polysilicon gates 28 are formed on gate dielectric 26. A capping layer 30 which is typically silicon nitride is formed on top of the polysilicon gate 28 so that the polysilicon gate is completely encapsulated after silicon nitride sidewalls 34 are formed. This is to prevent the top corners of the polysilicon gate from being exposed to SiGe epi growth. Epi blocking dielectric 32 is deposited over the integrated circuit prior to epi processing. An epi blocking pattern 36 is formed with an opening over the PMOS transistor area so that the epi blocking dielectric 32 may be etched form the PMOS region. The epi blocking layer 32 remains in the NMOS transistor region to block epi formation on NMOS transistors. The epi blocking layer 32 is typically silicon nitride.

FIG. 1B shows the integrated circuit after the epi blocking layer 32 is etched from the PMOS transistor area. Some overetch is typically used to ensure the epi blocking layer 32 is completely removed from the PMOS source and drain areas where trenches are to be etched in the single crystal silicon and replaced with epitaxially grown SiGe. On problem that may occur during overetch is that some of the STI dielectric 42 may be removed. The loss of the STI dielectric may result in the formation of a vertical convex corner 44 (FIG. 1C) when the SiGe trench is etched into the PMOS source and drains. SiGe may grow over this convex corner 44 and form dislocations that may cause increased diode leakage. Another problem that may occur during the overetch of the SiGe blocking layer is partial etching the sidewalls 34 on the PMOS transistor gate 28 resulting in exposure of the top corners 40 (FIG. 1B) of the PMOS transistor polysilicon gate 28. SiGe may grow on the exposed polysilicon 40 resulting in a contact to gate shorts.

FIG. 1C shows the integrated circuit after epi blocking pattern 36 is removed and trenches 46 are etched in the source and drain regions. A vertical convex corner 44 may form between the top corner of the silicon trench 46 and the STI dielectric 24 where a portion of the STI surface is removed during the epi blocking layer overetch. Polysilicon may also be exposed 40 at the top corners of the PMOS gate 28 where the height of the sidewalls 34 are reduced by the overetch of the SiGe blocking layer 32.

Referring now to FIG. 1D, SiGe 48 is epitaxially grown to refill the trenches in the PMOS source and drain areas. As shown in FIG. 1D, the SiGe may significantly overgrow 50 the vertical convex corner 44 formed in the recessed STI. Stress at the corner where SiGe overgrows 50 the convex corner 44 may cause crystal dislocations in the SiGe epi 48 resulting in higher diode leakage. In addition SiGe 48 may grow 52 on exposed polysilicon 40 where the sidewalls have been reduced in height by the overetch. SiGe protrusions 52 formed on the exposed poly 40 may result in electrical shorting of the PMOS gate 28 to contacts.

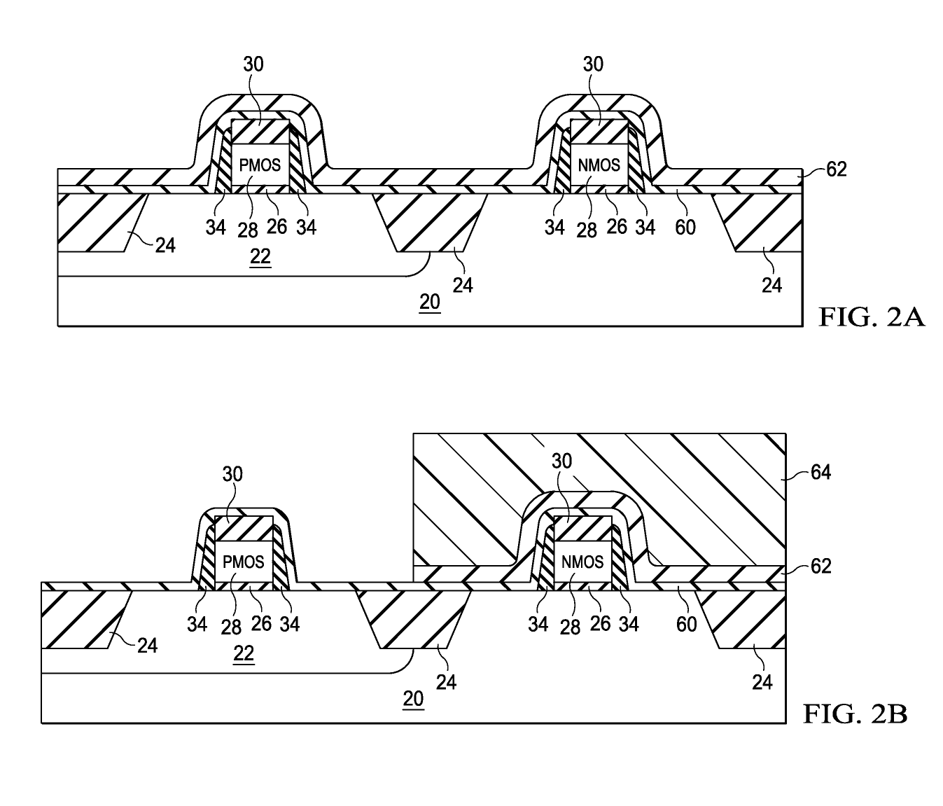

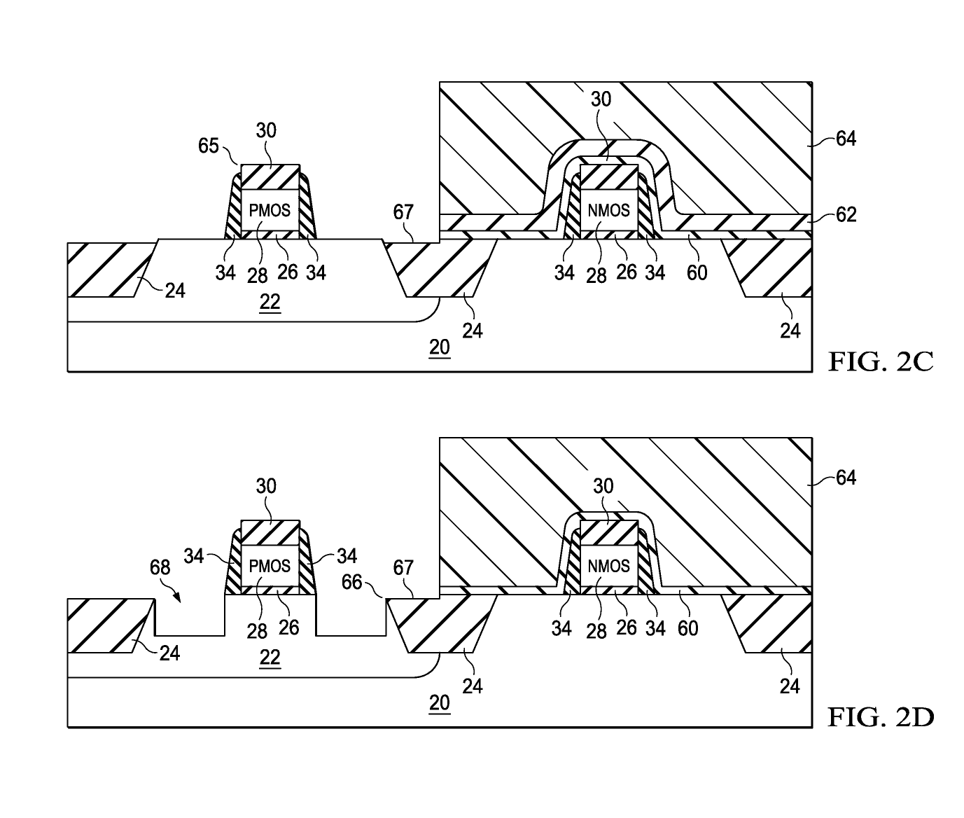

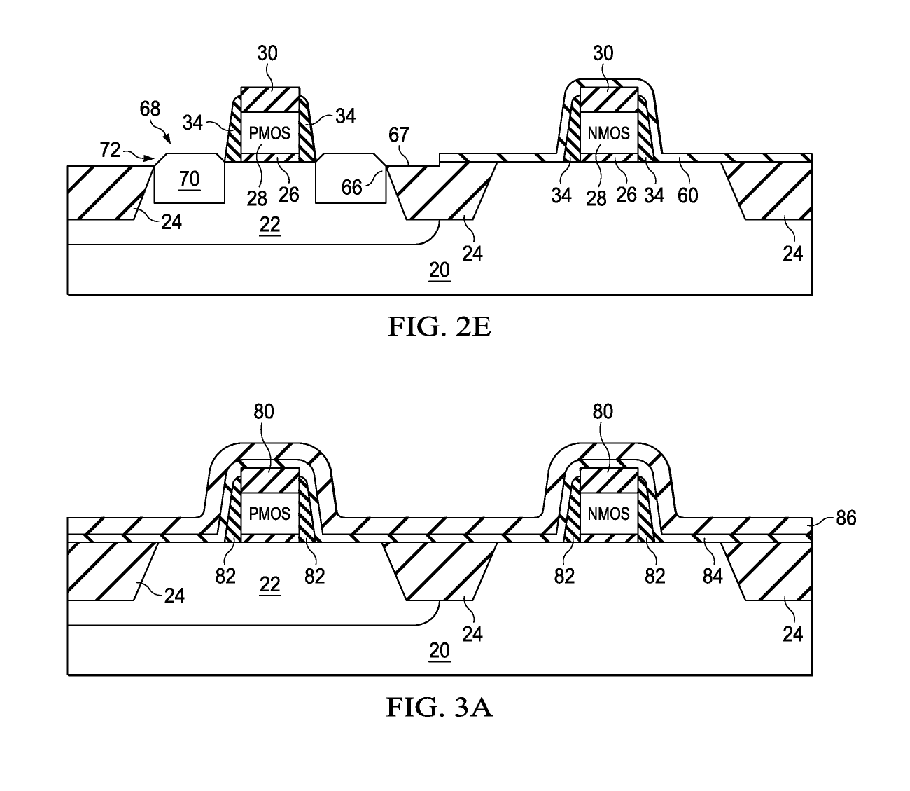

FIG. 2A through FIG. 2E illustrate steps in an embodiment method for growing embedded epi that essentially eliminates vertical convex corners where defects may form during epi growth. The embodiment also essentially eliminates the exposing of polysilicon on the top corners of PMOS gates where the growth of epi protrusions may result in contact to gate shorting. The embodiment method utilizes an epi blocking bilayer to block epi growth. The epi blocking bilayer significantly reduces diode leakage caused by defects at vertical convex corners and significantly reduces contact to gate shorts caused by epi protrusions growing on exposed polysilicon.

Depending upon whether the transistor sidewall dielectric and the transistor gate capping layer is silicon dioxide or silicon nitride, the epi blocking bilayer may be silicon nitride on silicon dioxide or may be silicon dioxide on silicon nitride. It is possible to also use other dielectrics such as silicon carbide, silicon oxynitride, and aluminum oxide in the embodiment epi blocking bilayer.

FIG. 2A shows an integrated circuit with an NMOS transistor on p-type substrate 20 and a PMOS transistor on nwell 22. Shallow trench isolation dielectric (STI) 24 electrically isolates the transistors. The transistor polysilicon gates 28 are formed on gate dielectric 26. A silicon nitride capping layer 30 is formed on the polysilicon gate 28 so that the polysilicon gate is completely encapsulated with silicon nitride dielectric after the silicon nitride sidewalls 34 are formed. In this example embodiment the capping layer 30 is silicon nitride on a thin layer of silicon dioxide. The capping layer 30 prevents polysilicon from being exposed during SiGe epi growth. In this embodiment the sidewalls 34 may be silicon nitride or may be an L-shaped spacer comprised of silicon nitride on a layer of silicon dioxide. The epi blocking bilayer in this illustration is comprised of a silicon nitride layer 62 deposited on a silicon dioxide layer 60. In an example embodiment silicon dioxide layer may be in the range of 3 nm to 5 nm and the silicon nitride layer may be in the range of 20 nm to 35 nm. In one embodiment the silicon dioxide layer is approximately 4 nm thick deposited using chemical vapor deposition (CVD) and the silicon nitride layer is approximately 30 nm thick deposited using CVD.

As shown in FIG. 2B an epi block photoresist pattern 64 that is open over the PMOS transistor regions and is covered over the NMOS transistor regions is formed on the epi blocking bilayer 62. The silicon nitride upper layer 62 of the embodiment epi blocking bilayer is etched from the PMOS region stopping on the silicon dioxide layer 60 of the epi blocking bilayer. Because the nitride plasma etch is selective to oxide, a significant amount of silicon nitride overetch may be used to completely remove the silicon nitride layer 62 without etching through the underlying silicon oxide 60 layer of the embodiment epi blocking bilayer. The nitride capping layer 30 and nitride sidewalls 34 on the PMOS transistor gate 28 are protected by the underlying silicon dioxide 60 epi blocking bilayer during the silicon nitride overetch so no polysilicon 28 is exposed.

The epi block photoresist pattern 64 may be removed prior to or after etching silicon dioxide layer 60. Typically silicon dioxide layer 60 is etched immediately after silicon nitride layer 62 in the same etch chamber with the epi block photoresist pattern 64 in place.

Referring now to FIG. 2C, the chemistry of the epi blocking plasma etch may be switched from a nitride etch with selectivity to oxide to an oxide etch with selectivity to nitride. The silicon dioxide layer 60 of the embodiment epi blocking bilayer may then be etched. Because the oxide etch has selectivity to nitride it may be removed without danger of reducing the height of the sidewalls 65 and exposing the top corner of the PMOS gate 28. Because the embodiment oxide layer 60 is thin it may be etched with little over etch and thus with minimal loss of the STI dielectric 24.

FIG. 2D shows the integrated circuit after the epi trenches 68 are etched into the PMOS transistor source and drain regions. Since the loss 67 of STI dielectic 24 is greatly reduced, the vertical convex corner 66 between the surface of the STI dielectric 24 and the trench 68 is not recessed to the point where significant epi overgrowth may occur. Since epi overgrowth is reduced, stress is reduced and defects that cause diode leakage are reduced.

Referring now to FIG. 2E, SiGe 70 is epitaxially grown to refill the trenches in the PMOS source and drain areas. As is illustrated in FIG. 2E, because the loss of STI dielectic 24 is small, little SiGe overgrowth 72 occurs over the convex corner 66 and therefore little stress develops. Few if any defects are generated due to the reduced stress so there is little if any increase in diode leakage due to defects in the SiGe. In addition, since no polysilicon on the PMOS gate is exposed, no SiGe epi protrusions (50 in FIG. 1D) grow on exposed polysilicon and contact to gate due to these protrusions is eliminated. After the SiGe epi 70 is grown the epi blocking bilayer layer is removed from the NMOS transistor region. Typically the silicon nitride 62 portion of the epi blocking bilayer is removed using a hot phosphoric wet etch and the silicon dioxide 60 portion of the epi blocking bilayer is removed with dilute HF.

By implementing an embodiment bilayer epi blocking layer, the process window for growing embedded epi without defects in the source and drain regions and without protrusions on exposed polysilicon gate corners is significantly increased.

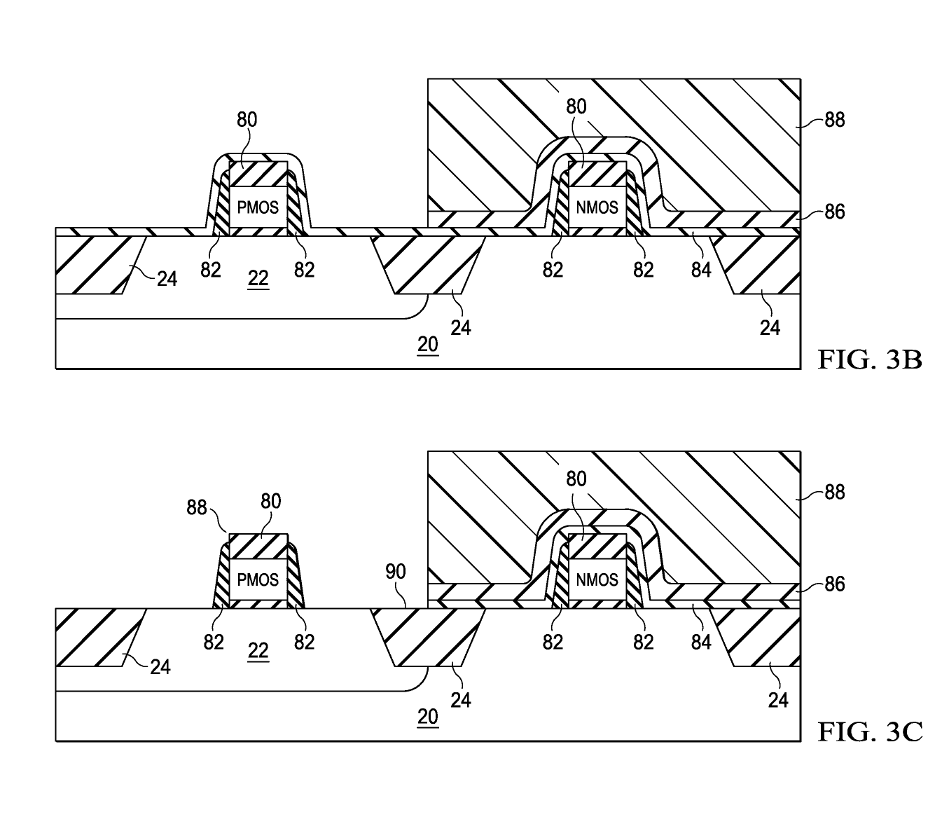

An alternative embodiment is illustrated in FIGS. 3A through 3C. This integrated circuit is the same as in FIG. 2A-2E except the capping layer 80 and the transistor sidewalls 82 in this integrated circuit are silicon dioxide instead of silicon nitride. In this embodiment the epi blocking bilayer is composed of a silicon dioxide layer 86 deposited on top of a silicon nitride layer 84. Because the silicon dioxide plasma etch is not quite as selective to silicon nitride as silicon nitride plasma etch is to silicon dioxide, the thickness of the silicon nitride 84 bottom bilayer may be thicker than the silicon dioxide 60 bottom bilayer in the previous embodiment. In an embodiment example the silicon nitride 84 layer may be in the range of 4 nm to 6 nm and the silicon dioxide 86 layer may be in the range of 20 nm to 30 nm. In one example embodiment the silicon dioxide 86 layer is approximately 5 nm thick deposited using CVD and the silicon nitride 84 layer is approximately 25 nm thick deposited using CVD.

In FIG. 3B an epi blocking photoresist pattern 88 is formed which blocks the epi block etch from NMOS transistor areas and opens the PMOS transistor areas to the epi block etch. The embodiment silicon dioxide epi blocking layer 86 is etched from the PMOS transistor regions stopping on the silicon nitride layer 84.

After the silicon dioxide epi blocking layer 86 is removed using a silicon dioxide plasma etch the etching chemistry may be changed to a silicon nitride etch with selectivity to silicon dioxide. As shown in FIG. 3C the lower embodiment silicon nitride layer 84 may then be removed using plasma etching. Because of the high selectivity of silicon nitride etch to silicon dioxide, the lower silicon nitride layer 84 may be etched from the STI dielectric causing little to no reduction in thickness 90 of the STI dielectric 24 where it is exposed. Also because of the high selectivity of silicon nitride etch to silicon dioxide, there is little to no reduction in height 92 of the silicon dioxide capping layer 80 and sidewalls 82.

The epi block photo resist pattern 88 is then removed and trenches are then etched in the PMOS transistor source and drain regions. SiGe is then epitaxially grown to fill the trenches as is described in the previous embodiment.

After SiGe epi growth, the silicon dioxide portion 86 of the epi blocking bilayer may then be removed with a dilute HF wet etch or an isotropic oxide plasma etch. The silicon nitride portion 84 of the epi blocking bilayer is then typically removed using a hot phosphoric wet etch.

Additional processing to add source and drain dopants, silicide, premetal dielectric, contact plugs and layers of interconnect may be performed to complete the integrated circuit.

Although embedded SiGe epi on PMOS transistors is used to illustrate the embodiments, embedded SiC on NNOS transistors may also benefit from the embodiment epi blocking bilayers. Although embodiment epi blocking bilayers used for illustration are silicon dioxide and silicon nitride, other dielectric materials such as silicon oxynitride, silicon carbide, and aluminum oxide may also be used.

Those skilled in the art to which this invention relates will appreciate that many other embodiments and variations are possible within the scope of the claimed invention.

What is claimed is:

1. A process of forming an integrated circuit, comprising the steps:
forming a dielectric capping layer on NMOS and PMOS transistor gates;
forming dielectric sidewalls on the dielectric capping layer and on the NMOS and PMOS transistor gates so that the NMOS and PMOS transistor gates are enclosed on a top by the dielectric capping layer and on sides by the dielectric sidewalls after sidewall etch so no polysilicon is exposed;
depositing an epi blocking bilayer on the integrated circuit where the epi blocking bilayer is comprised of a lower dielectric layer and an upper dielectric layer;
forming an epi blocking photoresist pattern on the epi blocking bilayer covering a first transistor type and not covering a second transistor type;
etching the upper dielectric layer using a plasma etch with selectivity to the lower dielectric layer from the second transistor type;
etching the lower dielectric layer using a plasma etch with selectivity to the upper dielectric layer from the second transistor type;
etching trenches in source and drain regions of the second transistor type; and
refilling the trenches with epitaxially grown single crystal semiconductor.

2. The process of claim 1 where the second transistor type is a PMOS transistor and where the epitaxially grown single crystal semiconductor is SiGe.

3. The process of claim 1 where the second transistor type is a NMOS transistor and where the epitaxially grown single crystal semiconductor is SiC.

4. The process of claim 1 where the dielectric capping layer is silicon nitride and where the dielectric sidewalls are silicon nitride and where the upper dielectric layer is silicon nitride and where the lower dielectric layer is silicon dioxide.

5. The process of claim 4 where the silicon dioxide thickness is in the range of 3 nm to 5 nm and where the silicon nitride thickness is in the range of 20 nm to 35 nm.

6. The process of claim 4 where the silicon dioxide thickness is 4 nm and where the silicon nitride thickness is 30 nm thick.

7. The process of claim 1 where the dielectric capping layer is silicon dioxide where the dielectric sidewalls are silicon dioxide and where the upper dielectric layer is silicon dioxide and where the lower dielectric layer is silicon nitride.

8. The process of claim 7 where the silicon nitride thickness is in the range of 4 nm to 6 nm and where the silicon dioxide thickness is in the range of 20 nm to 30 nm.

9. The process of claim 7 where the silicon nitride thickness is 5 nm and where the silicon dioxide thickness is 25 nm.

10. The process of claim 1 where the NMOS and PMOS transistor gates are polysilicon.

11. A process of forming an integrated circuit, comprising the steps:
forming a silicon nitride capping layer on polysilicon NMOS and polysilicon PMOS transistor gates;
forming silicon nitride sidewalls on the capping layer and on the polysilicon NMOS and PMOS transistor gates so that the NMOS and PMOS transistor polysilicon gates are enclosed on a top by the capping layer and on sides by the sidewalls;
depositing an epi blocking bilayer on the integrated circuit where the epi blocking bilayer is comprised of a lower silicon dioxide layer and an upper silicon nitride layer;
forming an epi blocking photo resist pattern on the epi blocking bilayer covering a first transistor type and not covering a second transistor type;
etching the upper silicon nitride layer from the second transistor type using a silicon nitride plasma etch with selectivity to silicon dioxide;
etching the lower silicon dioxide layer from the second transistor type using a silicon dioxide plasma etch with selectivity to silicon nitride;
etching trenches in source and drain regions of the second transistor type; and
refilling the trenches with epitaxially grown single crystal semiconductor.

12. The process of claim 11 where the second transistor type is a PMOS transistor and where the epitaxially grown single crystal semiconductor is SiGe.

13. The process of claim 11 where the second transistor type is a NMOS transistor and where the epitaxially grown single crystal semiconductor is SiC.

14. The process of claim 10 where the silicon dioxide thickness is in the range of 3 nm to 5 nm and where the silicon nitride thickness is in the range of 20 nm to 35 nm.

15. The process of claim 11 where the silicon dioxide thickness is 4 nm thick and where the silicon nitride thickness is 30 nm thick.

16. A process of forming an integrated circuit, comprising the steps:
forming a silicon dioxide capping layer on polysilicon NMOS and polysilicon PMOS transistor gates;
forming silicon dioxide sidewalls on the capping layer and on the polysilicon NMOS and PMOS transistor gates so that the NMOS and PMOS transistor polysilicon gates are enclosed on a top by the capping layer and on sides by the sidewalls;
depositing an epi blocking bilayer on the integrated circuit where the epi blocking bilayer is comprised of a lower silicon nitride layer and an upper silicon dioxide layer;
forming an epi blocking photo resist pattern on the epi blocking bilayer covering a first transistor type and not covering a second transistor type;
etching the upper silicon dioxide layer from the second transistor type using a silicon dioxide plasma etch with selectivity to silicon nitride;
etching the lower silicon nitride layer from the second transistor type using a silicon nitride plasma etch with selectivity to silicon dioxide;
etching trenches in source and drain regions of the second transistor type; and
refilling the trenches with epitaxially grown single crystal semiconductor.

17. The process of claim 16 where the second transistor type is a PMOS transistor and where the epitaxially grown single crystal semiconductor is SiGe.

18. The process of claim 16 where the second transistor type is a NMOS transistor and where the epitaxially grown single crystal semiconductor is SiC.

19. The process of claim 16 where the silicon nitride thickness is in the range of 4 nm to 6 nm and where the silicon dioxide thickness is in the range of 20 nm to 30 nm.

20. The process of claim 16 where the silicon nitride thickness is 5 nm and where the silicon dioxide thickness is 25 nm.
